(19) United States
(12) Patent Application Publication
(10) Pub. No.: US 2007/0148787 A1
(43) Pub. Date: Jun. 28, 2007

(54) Method for fabricating semiconductor device

(75) Inventors: Kenji Kiuchi, Kawasaki (JP); Genichi Komuro, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/405,622

(22) Filed: Apr. 18, 2006

(30) Foreign Application Priority Data
Dec. 28, 2005 (JP) 2005-377855

(51) Int. Cl. H01L 21/00

(52) U.S. Cl. 438/3

(57) ABSTRACT

A method for fabricating a semiconductor device that prevents an etching residue left at the time of making a contact hole which connects with a ferroelectric capacitor from adhering to the surface of a wafer. In order to make a contact hole which connects with an upper electrode or a lower electrode of the ferroelectric capacitor, a resist mask with predetermined thickness is formed and etching is performed so as to make the shape of the resist mask around an opening after the making of the contact hole taper as a result of widening the diameter of the opening and to make the thickness of a vertical portion of the resist mask around the opening approximately zero. Therefore, even if an etching residue left as a result of, for example, the over-etching of an electrode material adheres to the sidewall of the opening in the resist mask having a taper shape, the etching residue is removed by the etching. As a result, the possibility that the etching residue remains after the etching is small.

### CROSS-REFERENCE TO RELATED APPLICATIONS

This application is based upon and claims the benefits of priority from the prior Japanese Patent Application No. 2005-377855, filed on Dec. 28, 2005, the entire contents of which are incorporated herein by reference.

### BACKGROUND OF THE INVENTION

(1) Field of the Invention

This invention relates to a method for fabricating a semiconductor device and, more particularly, to a method for fabricating a semiconductor device having a ferroelectric capacitor.

(2) Description of the Related Art

Flash memories and ferroelectric memories are known as nonvolatile memories that can hold information after power is turned off.

A flash memory includes a floating gate embedded in a gate insulating film of an insulated gate field-effect transistor (IGFET) and stores information by accumulating electric charges indicative of the information to be stored in the floating gate. However, the disadvantage of such a flash memory is that a tunnel current must be passed through a gate insulating film at the time of writing or erasing information and that a comparatively high voltage must be applied.

On the other hand, a ferroelectric memory is also known as a ferroelectric random access memory (FeRAM) and stores information by utilizing the hysteresis characteristic of a ferroelectric film included in a ferroelectric capacitor. The ferroelectric film polarizes according to voltage applied between upper and lower electrodes of the capacitor. Even after the application of the voltage is stopped, spontaneous polarization remains. When the polarity of the applied voltage is reversed, the spontaneous polarization is also reversed. By associating the direction of the spontaneous polarization with “1” and “0,” information is written to the ferroelectric film. Voltage needed for this writing is lower than voltage needed for writing information to a flash memory. In addition, the speed at which information is written to an FeRAM is greater than that at which information is written to an flash memory. An FeRAM has these advantages.

A memory cell in an FeRAM includes a switching transistor and a ferroelectric capacitor. To fabricate an FeRAM, a metal oxide semiconductor (MOS) transistor, being the switching transistor, is formed and the ferroelectric capacitor is then formed above the MOS transistor (see, for example, Japanese Patent Laid-Open Publication No. 2004-63891).

FIG. 7 is a sectional view showing an important part of a semiconductor device at one stage in a conventional process for fabricating an FeRAM.

A MOS transistor section 50 included in memory cell in an FeRAM is formed in, for example, an element region in a well 53 of a predetermined conductive type defined in a silicon substrate 51 by a field oxide film 52. Source/drain regions (S/D's) 54a, 54b, and 54c and source/drain extensions (SDEs) 55a, 55b, and 55c are formed in the well 53. A polycrystalline silicon gate electrode 56a and a refractory metal (tungsten silicide, for example) film 57a are formed so as to overlap the S/D's 54a and 54b with a gate oxide film (not shown) between. Similarly, a polycrystalline silicon gate electrode 56b and a refractory metal film 57b are formed so as to overlap the S/D's 54b and 54c with a gate oxide film (not shown) between.

An etching stopper layer (silicon nitride (SiN) film, for example) 58 is formed so as to cover the MOS transistor section 50 formed in the above way. An insulating layer 59 is formed on the etching stopper layer 58. Plugs (tungsten plugs, for example) 60a, 60b, and 60c for connecting the S/D's 54a, 54b, and 54c, respectively, to a layer over them are formed in the insulating layer 59. Barrier metal films 61a, 61b, and 61c are formed on the sidewalls and bottoms of the plugs 60a, 60b, and 60c respectively. An anti-oxidation film (silicon oxide nitride (SiON) film, for example) 62 is formed on the insulating layer 59 and the plugs 60a, 60b, and 60c.

Ferroelectric capacitor sections 70a and 70b are formed over the anti-oxidation film 62 with an insulating layer 63 between. The ferroelectric capacitor section 70a includes a lower electrode 72a, a ferroelectric layer 73a, and an upper electrode 74a formed on an alumina (Al₂O₃) film 71 formed on the insulating layer 63 in that order so as to form the shape of stairs. Similarly, the ferroelectric capacitor section 70b includes a lower electrode 72b, a ferroelectric layer 73b, and an upper electrode 74b formed on the alumina (Al₂O₃) film 71 formed on the insulating layer 63 in that order so as to form the shape of stairs. The lower electrodes 72a and 72b are formed by using, for example, platinum (Pt). The ferroelectric layers 73a and 73b are formed by using, for example, lead zirconium titanate (PZT). The upper electrodes 74a and 74b are formed by using, for example, iridium oxide (IrO). An alumina film 75 is formed so as to cover the lower electrodes 72a and 72b, the ferroelectric layers 73a and 73b, and the upper electrodes 74a and 74b.

An insulating layer 76 is formed so as to cover the ferroelectric capacitor sections 70a and 70b. An alumina layer 77 is formed on the insulating layer 76 so that hydrogen or the like will not deteriorate the ferroelectric capacitor section 70a or 70b. An insulating layer 78 is formed on the alumina layer 77.

In the process shown in FIG. 7, a resist mask 79 used for making contact holes which connect with the lower electrode 72a and the upper electrode 74a of the ferroelectric capacitor section 70a and the lower electrode 72b and the upper electrode 74b of the ferroelectric capacitor section 70b is formed on the insulating layer 78.

FIG. 8 is a sectional view showing an important part of the semiconductor device after the making of the contact holes.

By performing etching with the resist mask 79 shown in FIG. 7, contact holes 80 which connect with the lower electrode 72a and the upper electrode 74a included in the ferroelectric capacitor section 70a and the lower electrode 72b and the upper electrode 74b included in the ferroelectric capacitor section 70b are made. At this time the lower electrodes 72a and 72b and the upper electrodes 74a and 74b are over-etched and etching residues 81 including Pt and Ir used for forming the electrodes adhere to the sidewalls of the contact holes 80 and the sidewalls of openings in the resist mask 79.

FIG. 9 is a sectional view showing an important part of the semiconductor device after the removal of the resist mask.

After the etching is performed, wet treatment is performed (by using, for example, nitric acid (HNO₃)) and the resist mask 79 is stripped by ashing.

However, the etching residues 81 including Pt and Ir used for forming the electrodes are not reactive, so it is difficult to remove the etching residues 81 by wet treatment with nitric acid or the like. Accordingly, after the resist mask 79 is stripped, the etching residues 81 which adhered to the sidewalls of the openings in the resist mask 79 remain in a state in which they are protruding from the contact holes 80, as shown in FIG. 9.

FIGS. 10A, 10B, 10C, and 10D are photographs showing the shape of a contact hole after conventional etching.

In this example, the thickness of a resist mask before etching is 1.18 μm. FIG. 10A shows the shape of the contact hole after the etching, wet treatment, and ashing. As can be seen from FIG. 10A, an etching residue which protrudes from the contact hole has fallen and looks like a flower. To remove this etching residue, the following processes must be performed.

FIG. 10B shows the shape of the contact hole after the process of removing the etching residue with a brush scrubber in which a brush is rotated and moved on a wafer.

FIG. 10C shows the shape of the contact hole after the above process of using a brush scrubber and the process of performing wet treatment by using nitric acid.

FIG. 10D shows the shape of the contact hole after the above process of using a brush scrubber, the above process of performing wet treatment by using nitric acid, and the process of using a brush scrubber again.

As stated above, it takes a long time to remove the etching residue protruding from the contact hole.

If the etching residue cannot be removed completely, some of it may scatter and adhere to the surface of the wafer. In this case, the following problem may arise.

FIG. 11 is a sectional view showing an important part of the semiconductor device in a process for making contact holes which connect with the MOS transistor section.

After the contact holes 80 which connect with the ferroelectric capacitor sections 70a and 70b are made, contact holes 90a, 90b, and 90c which connect with the plugs 60a, 60b, and 60c, respectively, of the MOS transistor section 50 are made. The reason for this is that after the contact holes 80 are made, annealing is performed for restoring damage to the ferroelectric capacitor sections 70a and 70b caused by the etching. That is to say, if at this time the contact holes 90a, 90b, and 90c which connect with the MOS transistor section 50 have been made, a metal material (tungsten, for example) used for forming the plugs 60a, 60b, and 60c is oxidized.

However, if etching residues 81a left in the process of making the contact holes 80 scatter and adhere to the surface of the wafer, the etching residues 81a constitute an obstacle to the making of the contact holes 90a, 90b, and 90c which connect with the MOS transistor section 50. In addition, the contact holes 90b and 90c, for example, taper. This leads to bad contact.

### SUMMARY OF THE INVENTION

The present invention was made under the background circumstances described above. An object of the present invention is to provide a semiconductor device fabrication method which prevents an etching residue left at the time of making contact holes that connect with a ferroelectric capacitor from adhering to the surface of a wafer.

In order to achieve the above object, a method for fabricating a semiconductor device having a ferroelectric capacitor is provided. This method comprises the processes of forming a resist mask with predetermined thickness for making a contact hole which connects with an upper electrode or a lower electrode of the ferroelectric capacitor; and making the contact hole by performing etching so as to make a shape of the resist mask around an opening after the making of the contact hole taper as a result of widening a diameter of the opening and to make thickness of a vertical portion of the resist mask around the opening approximately zero.

The above and other objects, features and advantages of the present invention will become apparent from the following description when taken in conjunction with the accompanying drawings which illustrate preferred embodiments of the present invention by way of example.

### BRIEF DESCRIPTION OF THE DRAWINGS

FIG. 1 are views for describing a feature of a method for fabricating a semiconductor device, according to an embodiment of the present invention.

FIG. 2 is a sectional view showing an important part of a semiconductor device at one stage in a process for fabricating an FeRAM.

FIG. 3 is a sectional view showing an important part of the semiconductor device after etching.

FIG. 4 is a sectional view showing an important part of the semiconductor device after the removal of a resist mask.

FIGS. 5A, 5B, 5C, and 5D are photographs showing the shape of a contact hole made by the method for fabricating a semiconductor device, according to the embodiment of the present invention.

FIG. 6 is a sectional view showing an important part of the semiconductor device in a process for making contact holes which connect with a MOS transistor section.

FIG. 7 is a sectional view showing an important part of a semiconductor device at one stage in a conventional process for fabricating an FeRAM.

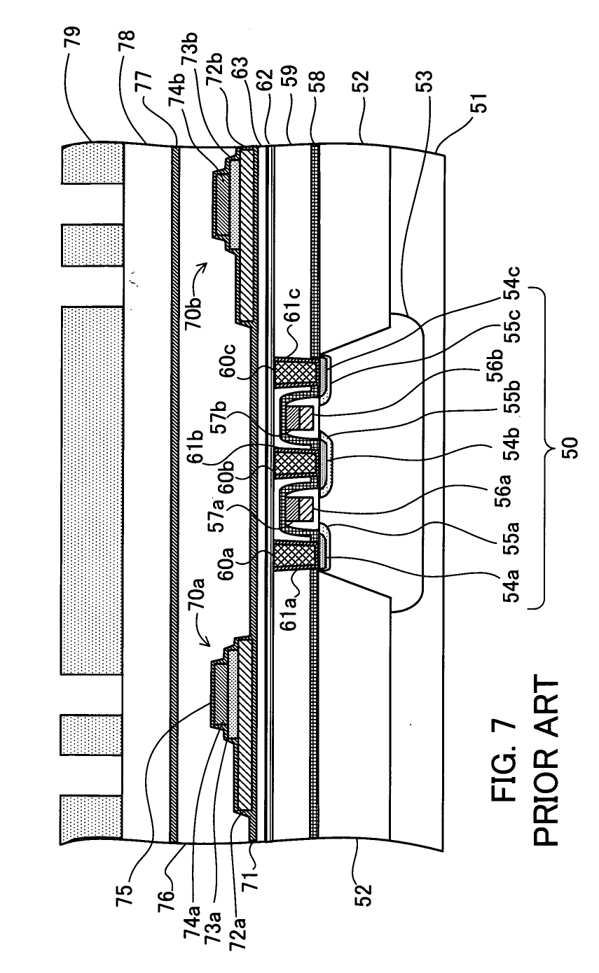

FIG. 8 is a sectional view showing an important part of the semiconductor device after the making of contact holes.

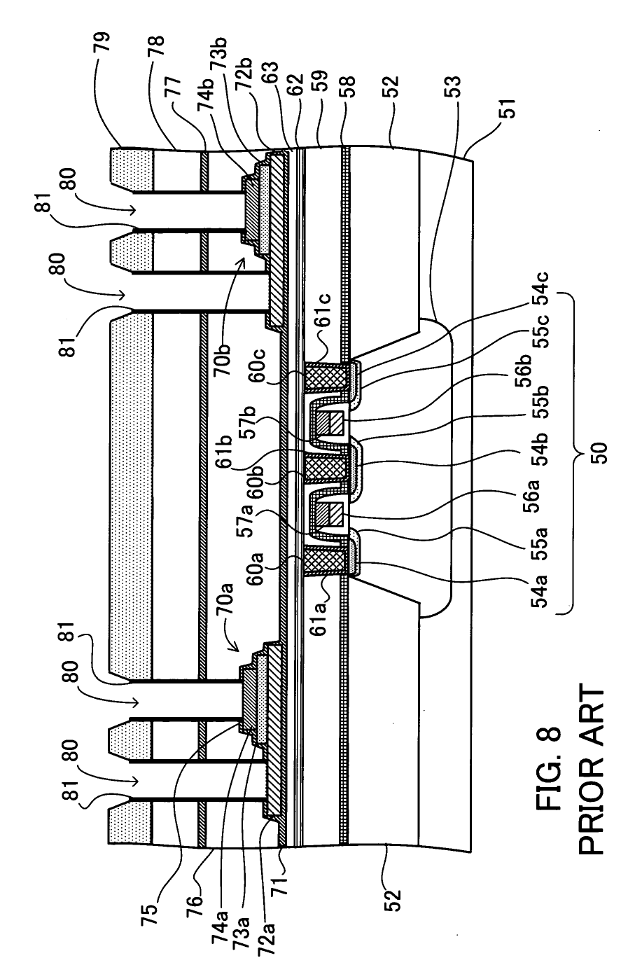

FIG. 9 is a sectional view showing an important part of the semiconductor device after the removal of a resist mask.

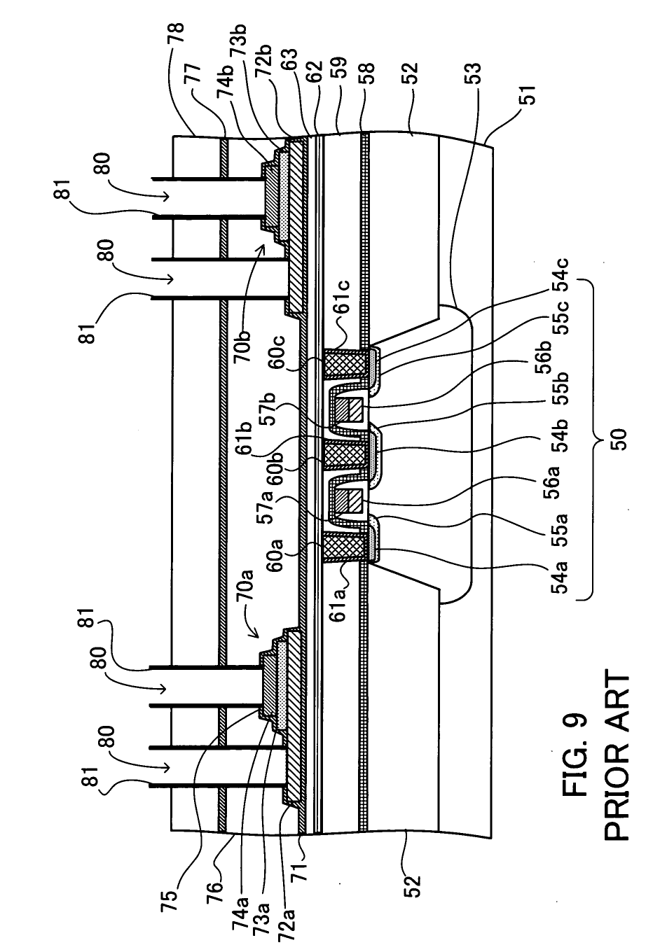

FIGS. 10A, 10B, 10C, and 10D are photographs showing the shape of a contact hole after conventional etching.

FIG. 11 is a sectional view showing an important part of the semiconductor device in a process for making contact holes which connect with a MOS transistor section.

### DESCRIPTION OF THE PREFERRED EMBODIMENT

An embodiment of the present invention will now be described in detail with reference to the drawings.

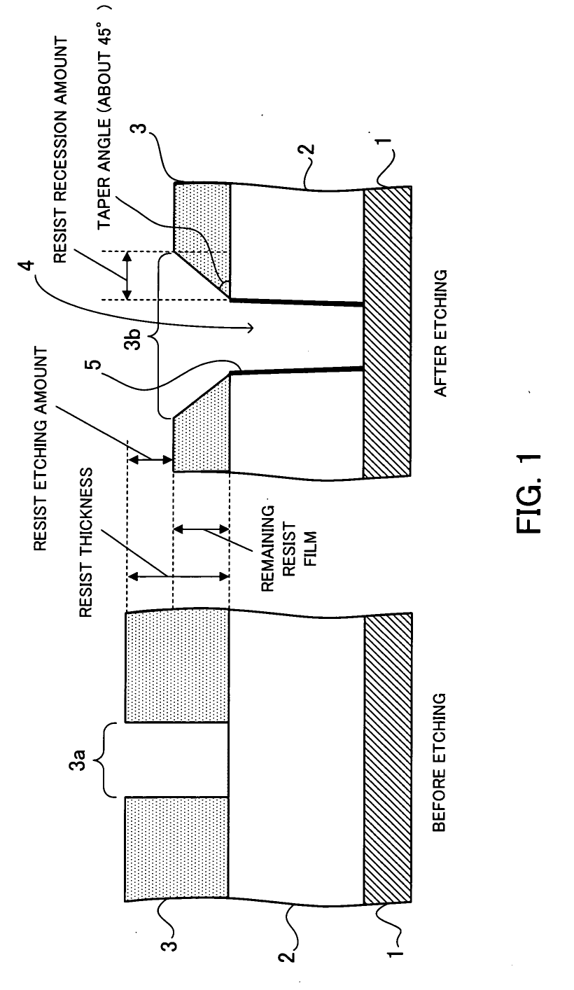

FIG. 1 are views for describing a feature of a method for fabricating a semiconductor device, according to an embodiment of the present invention. A sectional view showing an important part of a semiconductor device before etching is on the left-hand side and a sectional view showing an important part of the semiconductor device after etching is on the right-hand side.

In FIG. 1, only a portion where a contact hole which connects with an electrode 1 of a ferroelectric capacitor is made is shown. As shown in the view on the left-hand side of FIG. 1, when the contact hole is made, an insulating layer 2 has been formed on the electrode 1 of the ferroelectric capacitor. A resist mask 3 with predetermined thickness is formed on the insulating layer 2. In this case, a sidewall of an opening 3a made in the resist mask 3 by a photolithography technique is approximately vertical.

Etching is performed with the above resist mask 3 to make a contact hole 4. As shown in the view on the right-hand side of FIG. 1, in the method for fabricating a semiconductor device according to the embodiment of the present invention, the diameter of an opening 3b in the resist mask 3 after the making of the contact hole 4 has been widened by the etching and the resist mask 3 around the opening 3b has a taper shape having a taper angle of about 45°. In this case, the thickness of a vertical portion of the resist mask 3 around the opening 3b is made approximately zero by the etching. This is a feature of the method for fabricating a semiconductor device, according to the embodiment of the present invention.

An overview of a method for making the thickness of the vertical portion of the resist mask 3 around the opening 3b zero after the etching will now be given.

If the thickness of the vertical portion of the resist mask 3 around the opening 3b is zero, then the thickness of the resist mask 3 before the etching (resist thickness) equals the sum of a resist etching amount and the thickness of a resist portion having a taper shape. If a taper angle is 45°, then the thickness of the resist portion having a taper shape equals an increase in the diameter of the opening 3b (resist recession amount) Therefore, if the thickness of the vertical portion of the resist mask 3 around the opening 3b is zero,
resist thickness=resist etching amount+resist recession amount (1)

where
resist etching amount=resist etching rate in vertical direction×etching time
and
resist recession amount=rate of increase in diameter by etching (resist recession rate)×etching time.

Accordingly, the resist thickness or an etching condition should be controlled so as to satisfy equation (1). As shown in the view on the right-hand side of FIG. 1, this eliminates a vertical portion from a remaining resist film around the opening 3b and only a resist portion having a taper shape is left.

In the above method for fabricating a semiconductor device according to the embodiment of the present invention, even if an etching residue 5 left as a result of, for example, the over-etching of electrode materials adheres to the sidewall of the opening 3b in the resist mask 3 having a taper shape, the etching residue 5 is removed by etching. Accordingly, the possibility that the etching residue 5 remains after the etching is small. As a result, the etching residue 5 does not scatter or adhere to the surface of a wafer after the removal of the resist mask 3.

The method for fabricating a semiconductor device, according to the embodiment of the present invention will now be described in detail.

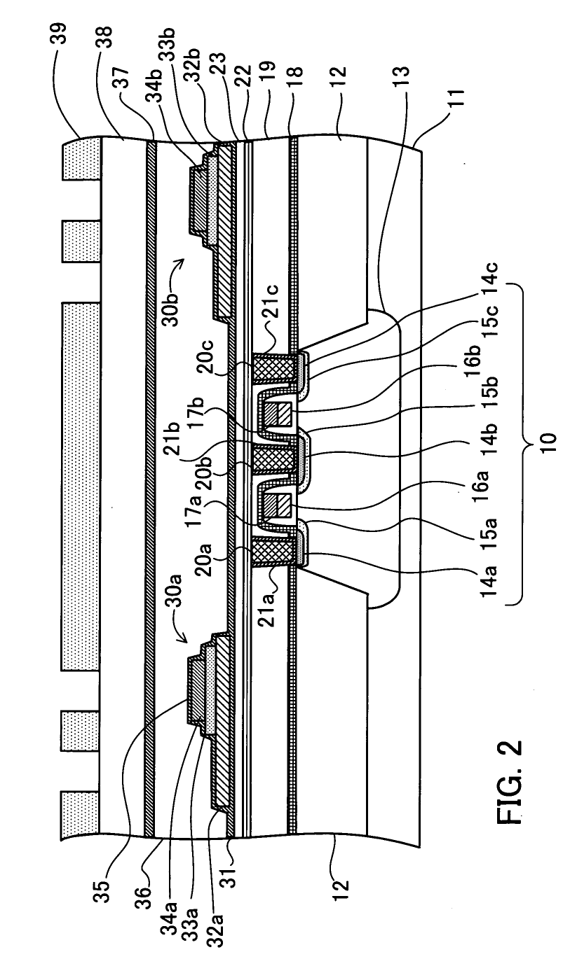

FIG. 2 is a sectional view showing an important part of a semiconductor device at one stage in a process for fabricating an FeRAM.

A memory cell in an FeRAM includes a switching transistor and a ferroelectric capacitor. A MOS transistor section 10, being a switching transistor, is formed in, for example, an element region in a well 13 of a predetermined conductive type defined in a silicon substrate 11 by a field oxide film 12. Source/drain regions (S/D's) 14a, 14b, and 14c and source/drain extensions (SDEs) 15a, 15b, and 15c are formed in the well 13. A polycrystalline silicon gate electrode 16a and a refractory metal (tungsten silicide, for example) film 17a are formed so as to overlap the S/D's 14a and 14b with a gate oxide film (not shown) between. Similarly, a polycrystalline silicon gate electrode 16b and a refractory metal film 17b are formed so as to overlap the S/D's 14b and 14c with a gate oxide film (not shown) between.

An etching stopper layer (silicon nitride film, for example) 18 is formed so as to cover the MOS transistor section 10 formed in the above way. An insulating layer 19 is formed on the etching stopper layer 18. Plugs (tungsten plugs, for example) 20a, 20b, and 20c for connecting the S/D's 14a, 14b, and 14c, respectively, to a layer over them are formed in the insulating layer 19. Barrier metal films 21a, 21b, and 21c are formed on the sidewalls and bottoms of the plugs 20a, 20b, and 20c respectively. An anti-oxidation film (silicon oxide nitride film, for example) 22 is formed on the insulating layer 19 and the plugs 20a, 20b, and 20c.

Ferroelectric capacitor sections 30a and 30b are formed over the anti-oxidation film 22 with an insulating layer 23 between. The ferroelectric capacitor section 30a includes a lower electrode 32a, a ferroelectric layer 33a, and an upper electrode 34a formed on an alumina film 31 formed on the insulating layer 23 in that order so as to form the shape of stairs. Similarly, the ferroelectric capacitor section 30b includes a lower electrode 32b, a ferroelectric layer 33b, and an upper electrode 34b formed on the alumina film 31 formed on the insulating layer 23 in that order so as to form the shape of stairs.

The lower electrodes 32a and 32b are formed by using, for example, platinum. The ferroelectric layers 33a and 33b are formed by using, for example, lead zirconium titanate. The upper electrodes 34a and 34b are formed by using, for example, iridium oxide.

An alumina film 35 with a thickness of about 20 nm is formed by a sputtering method so as to cover the lower electrodes 32a and 32b, the ferroelectric layers 33a and 33b, and the upper electrodes 34a and 34b.

An oxide film 36 is formed over the ferroelectric capacitor sections 30a and 30b by a chemical vapor deposition (CVD) method and is flattened by a chemical mechanical polishing (CMP) method. In this case, the thickness of the oxide film 36 over the lower electrodes 32a and 32b is set to, for example, about 670 nm and the thickness of the oxide film 36 over the upper electrodes 34a and 34b is set to, for example, about 300 nm. An alumina layer 37 with a thickness of about 50 nm is formed again on the flattened oxide film 36 by the sputtering method so that hydrogen or the like will not deteriorate the ferroelectric capacitor section 30a or 30b. An oxide film 38 with a thickness of about 300 nm is formed on the alumina layer 37 by the CVD method.

In the process shown in FIG. 2, a resist mask 39 having openings corresponding to contact holes which connect with the lower electrode 32a and the upper electrode 34a of the ferroelectric capacitor section 30a and the lower electrode 32b and the upper electrode 34b of the ferroelectric capacitor section 30b is then formed on the oxide film 38.

The thickness of the resist mask 39 is set according to etching conditions so as to satisfy equation (1). If the resist mask 39 is too thin, the function of a resist mask cannot be expected. As a result, the diameter of the contact holes becomes large or the shape of the contact holes formed by etching becomes inaccurate. Similarly, if a resist recession amount is too large, the diameter of the contact holes becomes large or the shape of the contact holes formed by etching becomes inaccurate. In the method for fabricating a semiconductor device according to the embodiment of the present invention, plasma etching is performed under the following etching conditions with the above points taken into consideration in order to make the contact holes which connect with the lower electrode 32a and the upper electrode 34a of the ferroelectric capacitor section 30a and the lower electrode 32b and the upper electrode 34b of the ferroelectric capacitor section 30b.

The thickness of the resist mask 39 is set to 750 nm. The thickness of the resist mask 39 can be controlled by the selection of a resist material, the number of revolutions made by a coater, or the like.

A parallel plate plasma etching system is used for performing etching. Octafluorocyclobutane (C₄F₈) gas, argon (Ar) gas, and oxygen (O₂) gas are used as etching gases and are passed at flow rates of 20, 500, and 16 sccm respectively. 2,200 W of high-frequency power is applied to an upper electrode of the plasma etching system and 1,400 W of high-frequency power is applied to a lower electrode of the plasma etching system. Pressure in the plasma etching system is 35 mTorr and the temperature of a wafer is 0° C.

When plasma etching was performed under the above conditions, a resist etching rate in the vertical direction was 150 nm/min (=2.5 nm/sec) and a resist recession rate was 85 nm/min (=1.42 nm/sec). If etching time is 190 seconds, then
resist etching amount=2.5×190=475 nm

and
resist recession amount=1.42×190=270 nm

The resist etching rate can be controlled by changing high-frequency power applied or the ratio of the flow rate of O₂ gas. The resist recession rate can be controlled by changing high-frequency power applied or the ratio of the flow rate of Ar gas.

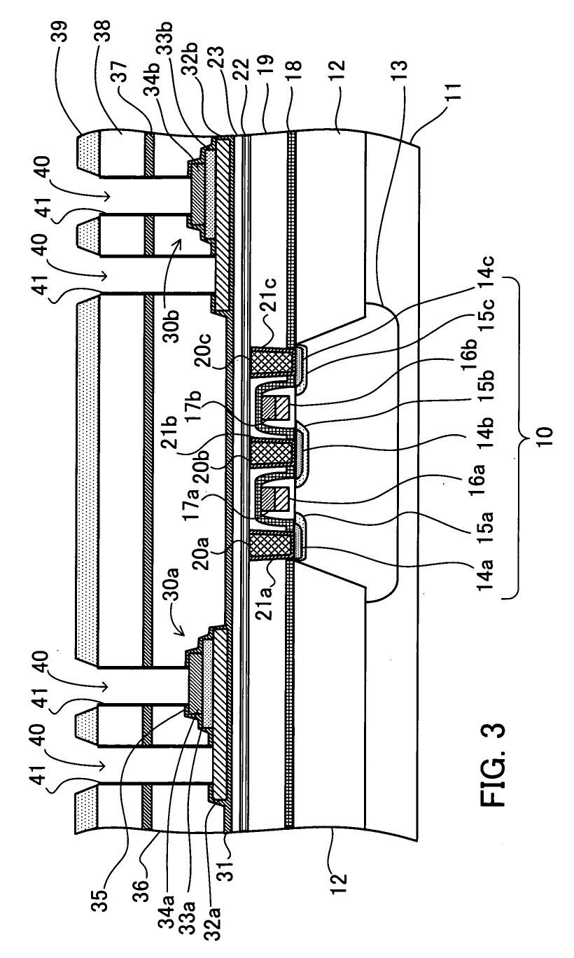

FIG. 3 is a sectional view showing an important part of the semiconductor device after the etching.

By performing the etching with the resist mask 39 shown in FIG. 2, contact holes 40 which connect with the lower electrode 32a and the upper electrode 34a of the ferroelectric capacitor section 30a and the lower electrode 32b and the upper electrode 34b of the ferroelectric capacitor section 30b are made. At this time the lower electrodes 32a and 32b and the upper electrodes 34a and 34b are over-etched and etching residues 41 including the electrode materials Pt and Ir adhere to the sidewalls of the contact holes 40.

By performing the etching under the above conditions, however, the sum (745 nm) of the resist etching amount and the resist recession amount becomes approximately equal to the thickness (750 nm) of the resist mask 39 before the etching and equation (1) is satisfied. As a result, as shown in FIG. 3, the resist mask 39 around each opening has a taper shape and there is almost no vertical resist portion around each opening. Therefore, an etching residue does not remain on the sidewall of each opening in the resist mask 39.

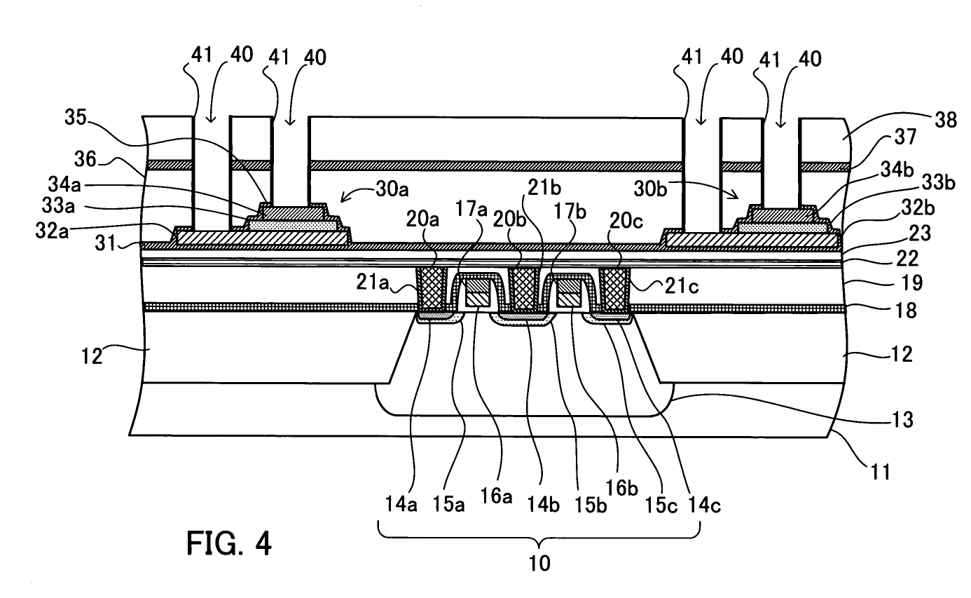

FIG. 4 is a sectional view showing an important part of the semiconductor device after the removal of the resist mask.

After the etching is performed, wet treatment is performed with nitric acid for 30 seconds and the resist mask 39 is stripped by ashing. Wet treatment is then performed again with nitric acid for 30 seconds. As shown in FIG. 4, an etching residue does not remain on the sidewalls of the openings in the resist mask 39 after the etching in the method for fabricating a semiconductor device, according to the embodiment of the present invention. Therefore, after the resist mask 39 is removed, an etching residue does not scatter or adhere to the surface of the wafer.

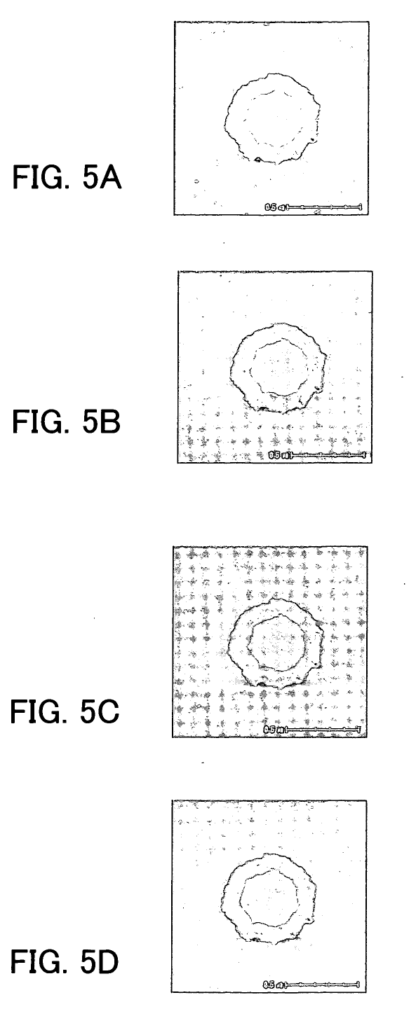

FIGS. 5A, 5B, 5C, and 5D are photographs showing the shape of a contact hole made by the method for fabricating a semiconductor device, according to the embodiment of the present invention.

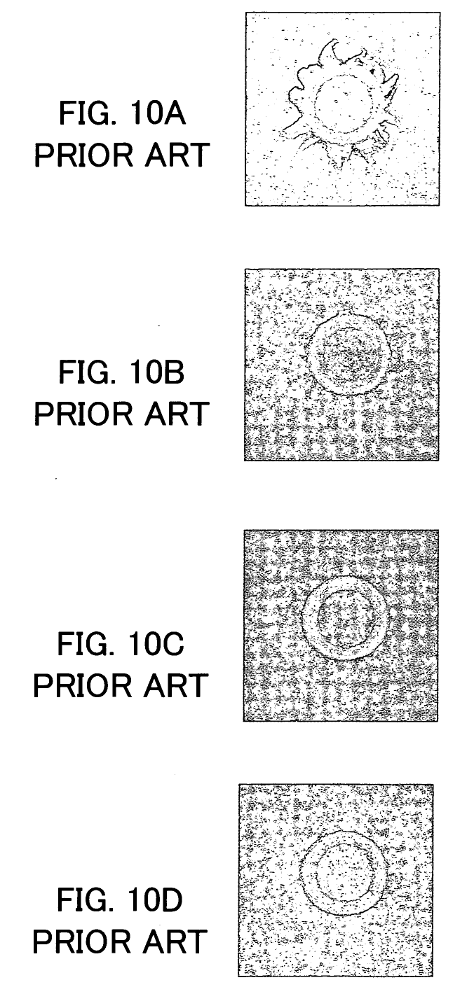

FIG. 5A shows the shape of the contact hole after etching, wet treatment, and ashing. In FIG. 10A, the flower-like etching residue is shown. Unlike the case of FIG. 10A where the conventional etching is performed, however, such an etching residue does not remain on the contact hole made by the method for fabricating a semiconductor device, according to the embodiment of the present invention.

The same processes that are performed in FIGS. 10B, 10C, and 10D are performed in FIGS. 5B, 5C, and 5D respectively. That is to say, FIG. 5B shows the shape of the contact hole after the process of using a brush scrubber. FIG. 5C shows the shape of the contact hole after the above process of using a brush scrubber and the process of performing wet treatment by using nitric acid. FIG. 5D shows the shape of the contact hole after the above process of using a brush scrubber, the above process of performing wet treatment by using nitric acid, and the process of using a brush scrubber again. However, the shape of the contact hole shown in FIG. 5B, 5C, or 5D is almost the same as the shape of the contact hole shown in FIG. 5A. This means that these processes are unnecessary in the method for fabricating a semiconductor device, according to the embodiment of the present invention. That is to say, the number of processes can be reduced.

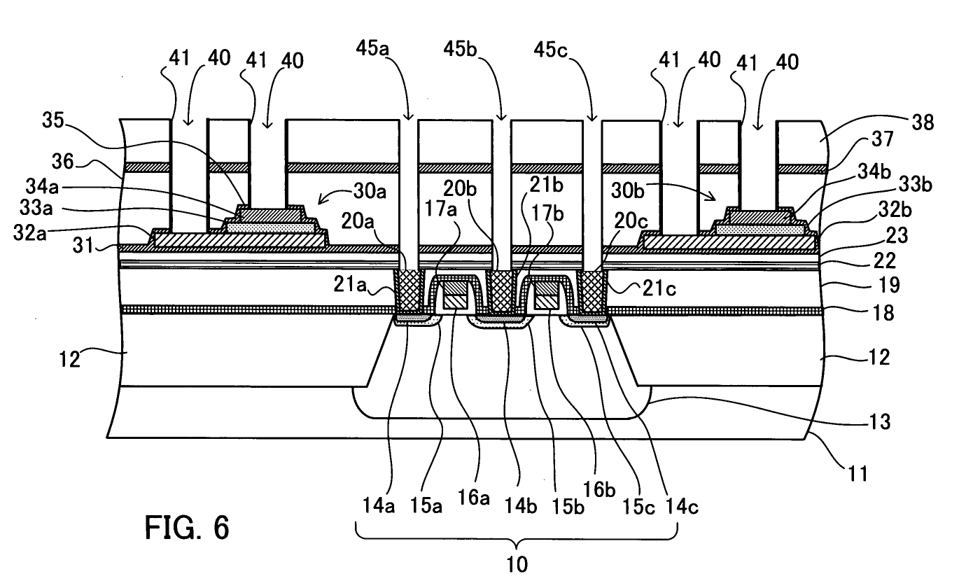

FIG. 6 is a sectional view showing an important part of the semiconductor device in a process for making contact holes which connect with the MOS transistor section.

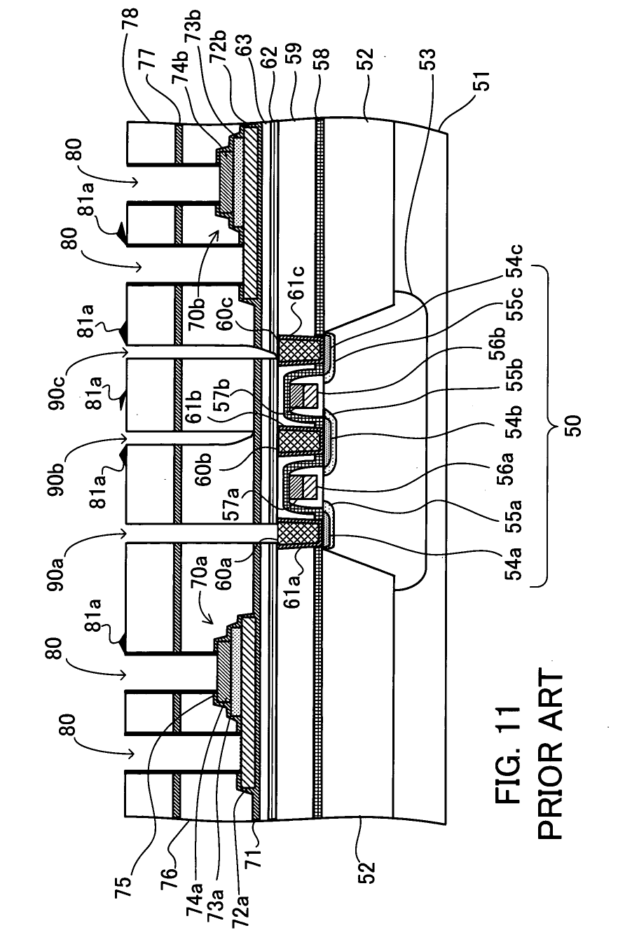

As stated above, the method for fabricating a semiconductor device, according to the embodiment of the present invention prevents an etching residue from adhering to the surface of the wafer. As a result, etching for making contact holes 45a, 45b, and 45c which connect with the MOS transistor section 10 is not hampered by, for example, the etching residues 81a shown in FIG. 11. Therefore, as shown in FIG. 6, good-quality contact holes which do not cause bad contact can be made and the yield can be improved.

In the present invention, even if an etching residue left as a result of, for example, the over-etching of an electrode material adheres to the sidewall of an opening in a resist mask having a taper shape at the time of making a contact hole which connects with an upper electrode or a lower electrode of a ferroelectric capacitor, the etching residue is removed by etching. Therefore, the possibility that the etching residue remains after the etching is small. As a result, the etching residue does not scatter or adhere to the surface of a wafer after the removal of the resist mask.

The foregoing is considered as illustrative only of the principles of the present invention. Further, since numerous modifications and changes will readily occur to those skilled in the art, it is not desired to limit the invention to the exact construction and applications shown and described, and accordingly, all suitable modifications and equivalents may be regarded as falling within the scope of the invention in the appended claims and their equivalents.

What is claimed is:

1. A method for fabricating a semiconductor device having a ferroelectric capacitor, the method comprising the processes of:
forming a resist mask with predetermined thickness for making a contact hole which connects with an upper electrode or a lower electrode of the ferroelectric capacitor; and
making the contact hole by performing etching so as to make a shape of the resist mask around an opening after the making of the contact hole taper as a result of widening a diameter of the opening and to make thickness of a vertical portion of the resist mask around the opening approximately zero.

2. The method according to claim 1, wherein the thickness of the vertical portion of the resist mask around the opening is made approximately zero by controlling the thickness of the resist mask.

3. The method according to claim 1, wherein the thickness of the vertical portion of the resist mask around the opening is made approximately zero by controlling an etching condition.

4. The method according to claim 1, wherein anisotropic etching is performed by using a parallel plate plasma etching system.

5. The method according to claim 1, wherein the thickness of the resist mask or an etching condition is controlled so as to satisfy
thickness of the resist mask=(resist etching rate in vertical direction×etching time)+(rate of increase in diameter of the opening by etching×etching time)

6. The method according to claim 5, wherein the resist etching rate in the vertical direction is controlled by high-frequency power applied to a plasma etching system or a ratio of a flow rate of oxygen gas at etching time.

7. The method according to claim 5, wherein the rate of the increase in the diameter of the opening by the etching is controlled by high-frequency power applied to a plasma etching system or a ratio of a flow rate of argon gas at etching time.

8. The method according to claim 5, wherein the thickness of the resist mask is controlled by a resist material or a number of revolutions made by a coater.
